(19) United States
(12) Patent Application Publication
(10) Pub. No.: US 2011/0193672 A1
(43) Pub. Date: Aug. 11, 2011

(54) MAGNETIC ELEMENT AND METHOD FOR MANUFACTURING THE SAME

(76) Inventor: Tzung-Hua YANG, Sanchong City (TW)

(21) Appl. No.: 12/703,978

(22) Filed: Feb. 11, 2010

(51) Int. Cl. H01F 27/24; B05D 5/12; H05K 3/00

(52) U.S. Cl. 336/233; 427/96.1; 216/13

(57) ABSTRACT

A magnetic element and a method for manufacturing the same are provided. The magnetic element may be applied to various electronic devices requiring magnetic elements, for example, communication circuits and transformer circuits. The magnetic element mainly includes a substrate and an iron core. The substrate has an accommodation slot formed thereon, and the iron core is assembled in the accommodation slot. Furthermore, the substrate and the iron core are respectively disposed with a vertical circuit, and the substrate further has a horizontal circuit disposed on an upper surface and a lower surface respectively. After the above components are assembled, each vertical circuit and each horizontal circuit are electrically connected, so as to form the magnetic element having an coil architecture.

### BACKGROUND OF THE INVENTION

1. Field of the Invention

The present invention relates to a magnetic element, applicable to be assembled in an electronic device, and more particularly to a magnetic element having an iron core disposed in a substrate and using a printed circuit to replace a wound coil, and a method for manufacturing the same.

2. Related Art

Generally, a so-called passive magnetic element, for example, a transformer, an inductor, or other common magnetic elements, generates a magnetic field once a current flows in the passive magnetic element. Taking a magnetic element of the inductor as an example, the magnetic element is mainly formed by an iron core and a coil. As for the inductor of this type, a manufacturing procedure of a winding part is rather complicated. Currently, the magnetic element is an important element for various electronic information devices, for example, a portable telephone has hundreds of types of passive elements assembled therein, and main functional operations are achieved by applying the magnetic elements. Especially, in terms of improving performances and diversifying functions, the amount of elements needs to be further expanded, so as to achieve the expected objective. However, nowadays, the information equipment tends to be light, thin, short, and small, such that the inserting, welding, and testing tasks of the elements become much difficult. In this case, the coil and the inductor are still configured on a ceramic substrate, and are manufactured by using a thick film technique or a hollow winding process.

As the electronic device is miniaturized, the miniaturization of the adopted elements and components is increasingly demanded. Therefore, another magnetic element having a different structure is provided in the prior art, which is applicable to reduce a volume of the magnetic element. For example, in US Patent Publication No. 20070063807, a magnetic component is provided, in which the magnetic component is mainly fabricated on a substrate, and an iron core is assembled in the substrate. A conductive pattern is disposed on the substrate, so as to form a coil after being assembled. Although the conductive pattern is used in this structure to replace the coil to facilitate reducing an entire volume of the magnetic element, other problems to be urgently solved still exist in the manufacturing process and the assembly process, such that a yield of the produced magnetic elements cannot be improved. The magnetic component is mainly formed by a first substrate and a second substrate, in which the second substrate has a conductive pattern disposed thereon and has an assembly slot formed thereon, and a boss is configured at a central position in the assembly slot. When the first substrate and the second substrate are adhered to each other, the force is non-uniformly applied on the boss due to the stress and extremely easily results in breaking of the second substrate, which may further result in an open circuit of the conductive pattern on the second substrate, so that a defective rate of the magnetic elements always maintains a high level.

### SUMMARY OF THE INVENTION

In view of the above problems, the present invention is mainly directed to a magnetic element, capable of being easily assembled and having accurate electrical connection points and a high yield, and a method for manufacturing the same.

In order to achieve the above objectives, the present invention provides a magnetic element, which mainly includes a substrate and an iron core. The substrate has an accommodation slot formed on a surface thereof, and several vertical circuits are disposed along an end edge of the accommodation slot. The iron core is assembled in the accommodation slot, a central area of the iron core is filled up with an insulating material, and additional vertical circuits are configured in the insulating material. Furthermore, the substrate has several horizontal circuits respectively disposed on an upper surface and a lower surface thereof. After the above components are assembled, each horizontal circuit on the upper surface and the lower surface of the substrate and each vertical circuit of the substrate and the iron core are electrically connected, so as to form a coil type circuit, thereby completing the fabrication of the magnetic element.

### BRIEF DESCRIPTION OF THE DRAWINGS

FIG. 1 is a three-dimensional outside view of the present invention;

FIG. 2 is a schematic view (1) of implementation of the present invention;

FIG. 3 is a schematic view (2) of implementation of the present invention;

FIG. 4 is a schematic view (3) of implementation of the present invention;

FIG. 5 is a schematic view (4) of implementation of the present invention;

FIG. 6 is a perspective top view of the present invention;

FIG. 7 is a schematic view (5) of implementation of the present invention;

FIG. 8 shows a first embodiment of the present invention;

FIG. 9 shows a second embodiment of the present invention;

FIG. 10 shows a third embodiment of the present invention;

FIG. 11 shows a fourth embodiment of the present invention; and

FIG. 12 is a schematic flow chart of a manufacturing method according to the present invention.

### DETAILED DESCRIPTION OF THE INVENTION

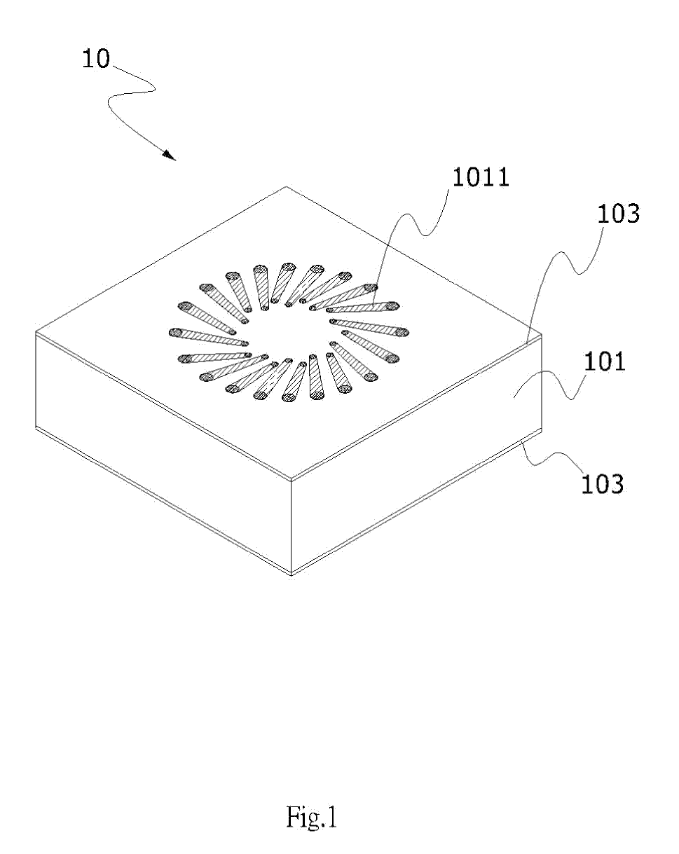

FIG. 1 is a three-dimensional outside view of the present invention. Referring to FIG. 1, a magnetic element 10 according to the present invention mainly includes a substrate 101 and an iron core (not shown in FIG. 1), in which surfaces of the substrate 101 have an insulating layer 103, and the substrate has several first horizontal circuits 1011 disposed thereon.

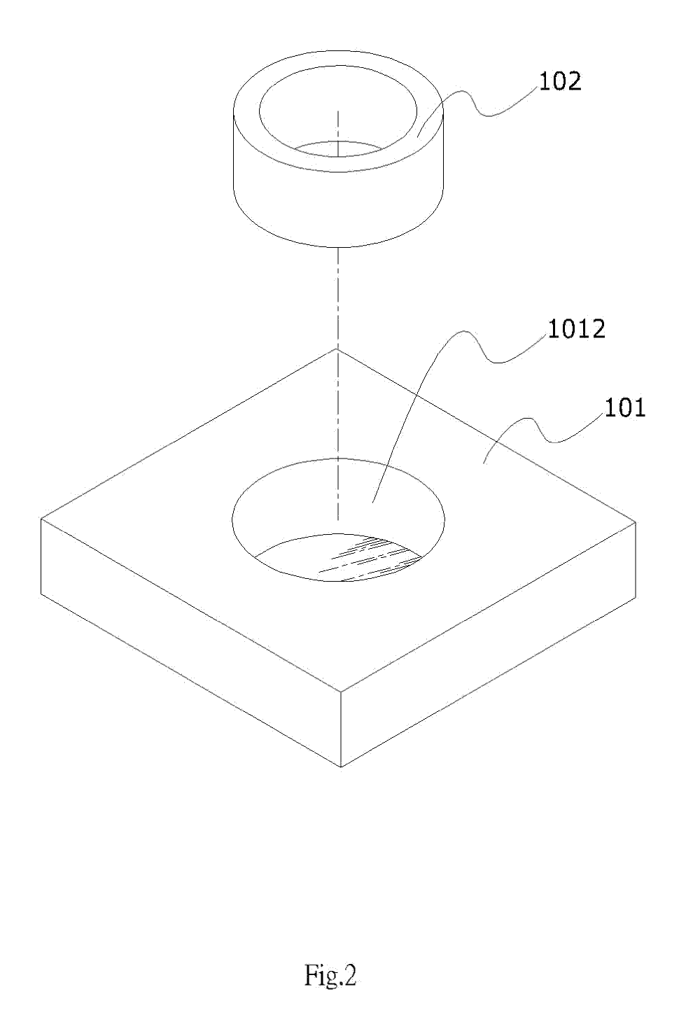

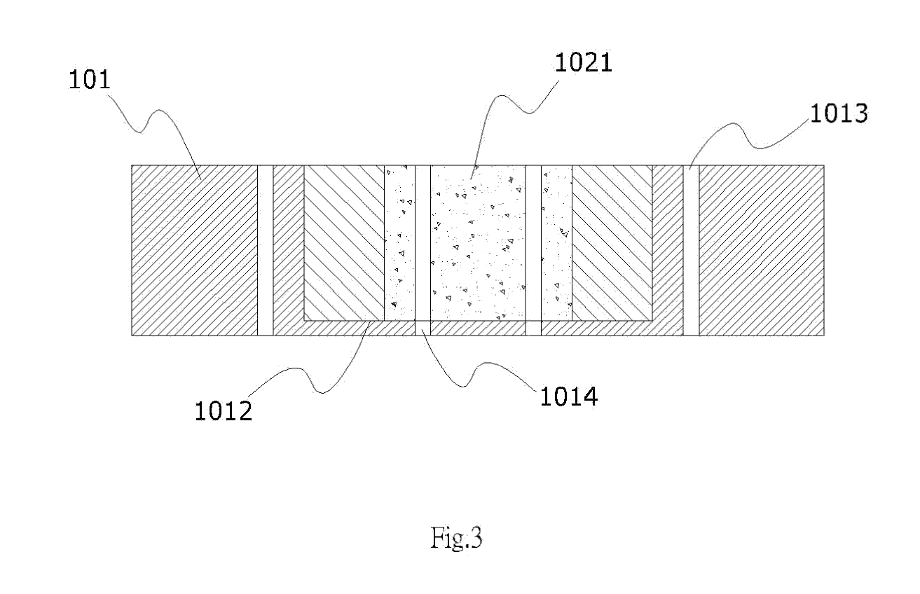

FIG. 2 is a schematic view (1) of implementation of the present invention, and FIG. 3 is a schematic view (2) of implementation of the present invention. Referring to FIGS. 2 and 3, during the implementation of the present invention, an accommodation slot 1012 is firstly formed on the surface of the substrate 101, and then the iron core 102 is placed in the accommodation slot 1012, in which a size of the accommodation slot 1012 corresponds to a size of the iron core 102, and the iron core 102 is hollow-shaped. After the iron core 102 has been assembled, an insulating material is filled into a hollow inner edge area of the iron core 102, and the insulating material is cured to form an insulator 1021. Furthermore, after the insulator 1021 is formed, several vertical through holes (1013 and 1014) are drilled on an end edge of the accommodation slot 1012 and the inner edge area of the iron core 102.

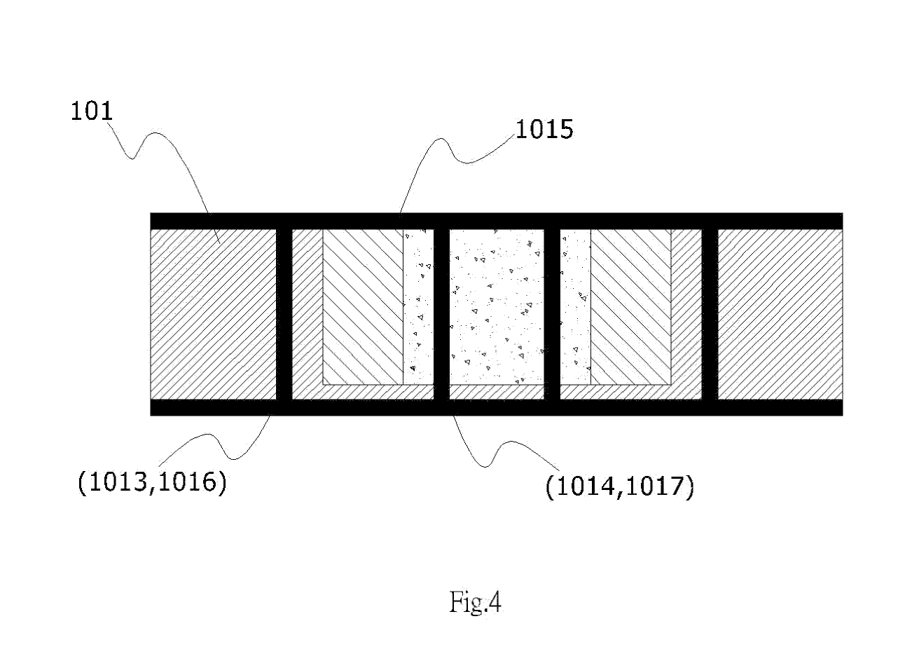

FIG. 4 is a schematic view (3) of implementation of the present invention. Referring to FIGS. 3 and 4, accordingly, after the vertical through holes (1013 and 1014) are drilled, a conductive material 1015 is coated on the upper surface and the lower surface of the substrate 101, and the vertical through holes (1013 and 1014) are filled up with the conductive material 1015, so as to form several first vertical circuits 1016 and several second vertical circuits 1017.

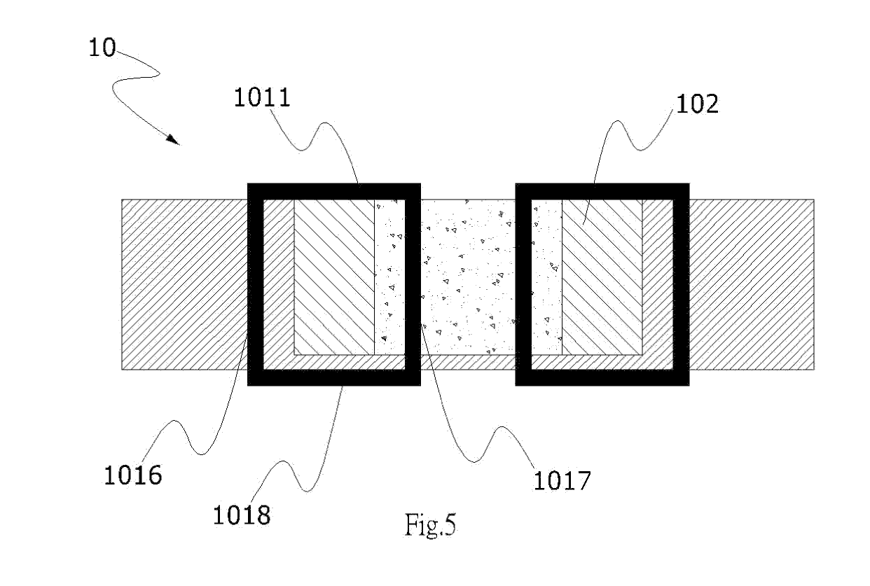

FIG. 5 is a schematic view (4) of implementation of the present invention. Referring to FIGS. 4 and 5, after the conductive material 1015 is coated, the conductive material 1015 to be reserved is processed through a photoelectric process, for example, exposure, development, and etching. After the process is finished, several first horizontal circuits 1011 are formed on the upper surface of the substrate 101, and several second horizontal circuits 1018 are formed on the lower surface. In this manner, the horizontal circuits (1011 and 1018) on the surfaces of the substrate and the vertical circuits (1016 and 1017) are electrically connected to form a coil configuration. Furthermore, the iron core 102 is surrounded by the coil formed by each circuit, so as to form the magnetic element 10.

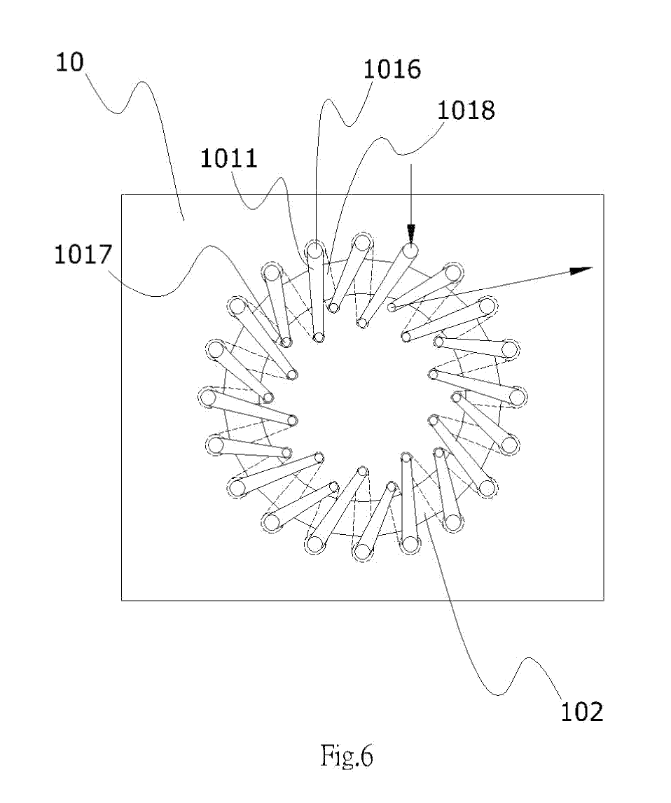

FIG. 6 is a perspective top view of the present invention. Referring to FIGS. 5 and 6, a layout of the coil-type circuit formed by each circuit is described as follows.

[First horizontal circuit 1011→first vertical circuit 1016→second horizontal circuit 1018→second vertical circuit 1017]→first horizontal circuit 1011→first vertical circuit 1016→ . . . . Accordingly, the above configuration in the brackets is one coil-type circuit, and when the coil-type circuit is subsequently connected to another first horizontal circuit 1011 again, it enters a second coil-type circuit. Furthermore, referring to FIGS. 5 and 6, the iron core 102 is surrounded by the coil-type circuits formed by each circuit, so as to form the magnetic element 10. Furthermore, as described in the present invention, each circuit of the magnetic element 10 is completed by using a printed circuit technique, such that during assembly, an accurate alignment effect may be achieved, such that a pitch between the adjacent horizontal circuits is the same (depending upon a preset value), and a pitch between the adjacent vertical circuits is also the same (depending upon a preset value). In this manner, not only the accurate electrical connection effect is achieved in the manufacturing process, but also the problem generated by the conventional winding is avoided, for example, when the coils are wound, pitches between the wires are inconsistent.

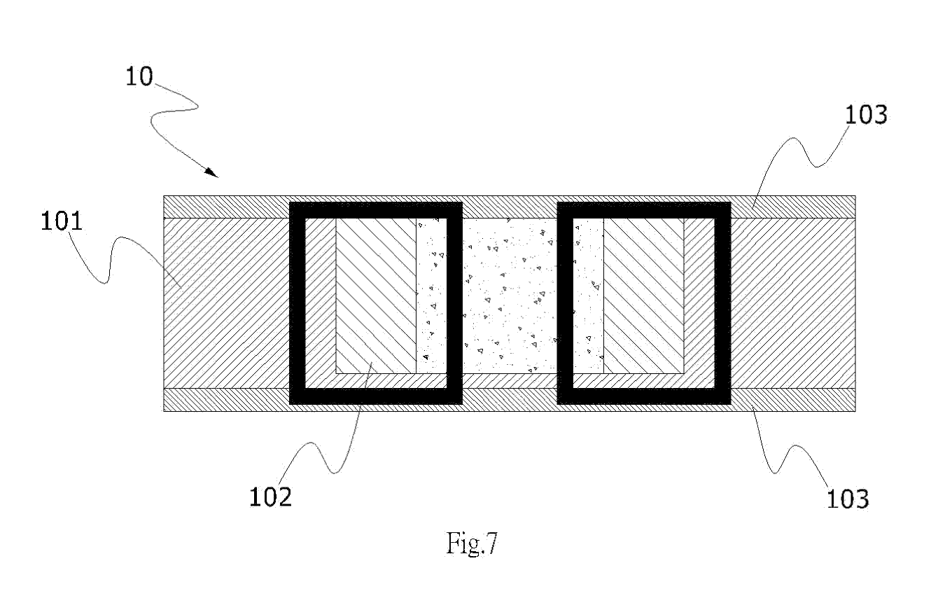

FIG. 7 is a schematic view (5) of implementation of the present invention. Referring to FIG. 7, in the magnetic element 10 according to the present invention, an insulating layer 103 is further coated on the upper surface and the lower surface of the substrate 101 respectively, such that each circuit disposed on the substrate 101 and the iron core 102 are protected by the insulating layers 103.

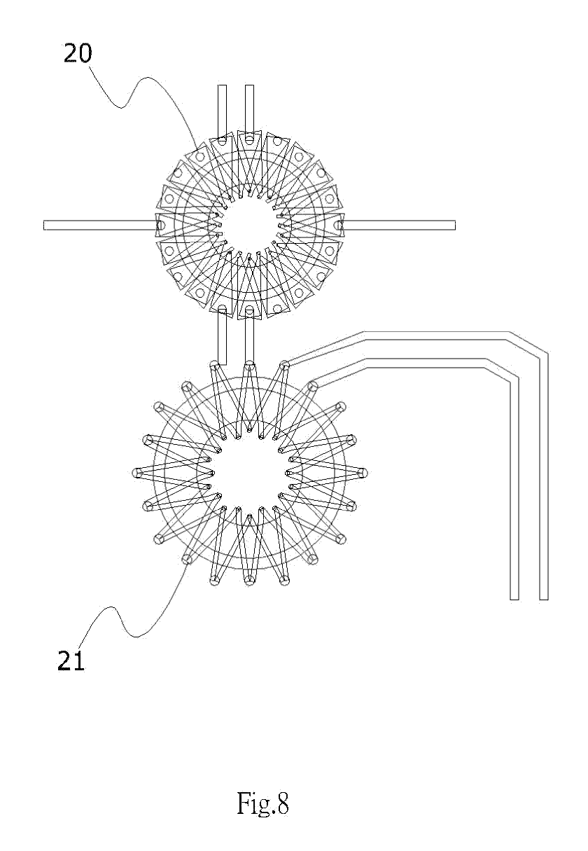

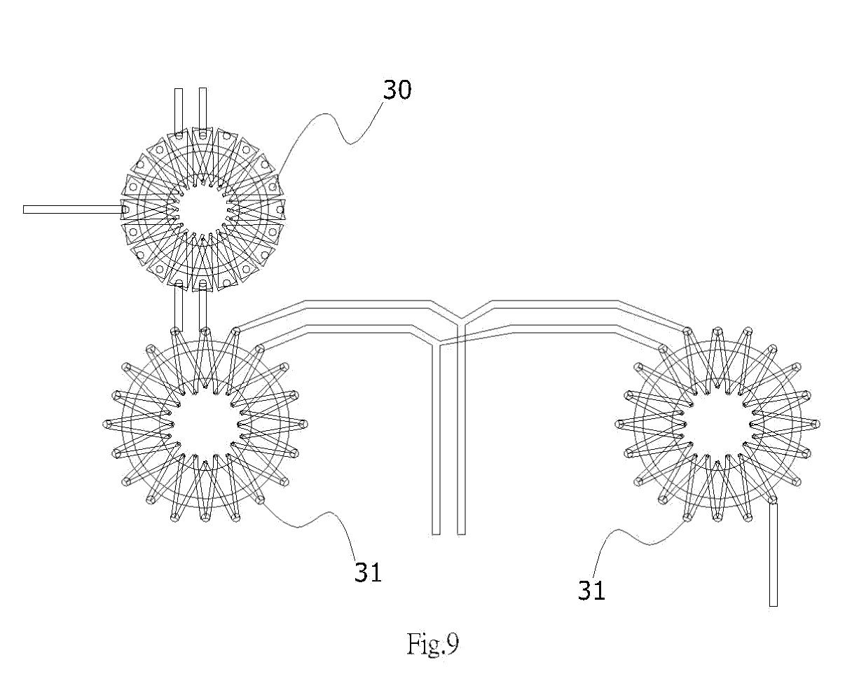

FIG. 8 shows a first embodiment of the present invention. Referring to FIG. 8, the structure of the present invention may be respectively formed into a transformer 20 and an inductor 21, which may be electrically connected in series or in parallel according to a circuit design. FIG. 9 shows a second embodiment of the present invention. Referring to FIG. 9, the structure of the present invention may be respectively formed into a transformer 30 and two inductors (31 and 32), which may be electrically connected to one another according to a circuit design.

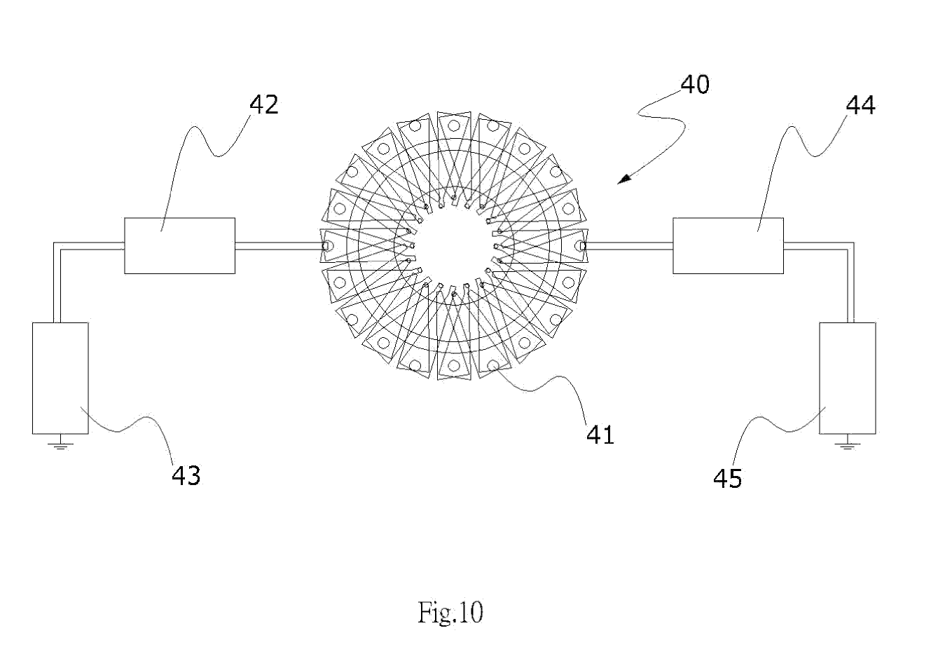

FIG. 10 shows a third embodiment of the present invention. Referring to FIG. 10, according to the circuit design, the magnetic element according to the present invention may be configured into a magnetic means 40, which mainly includes a magnetic element 41 that may be formed into a transformer or inductor according to a circuit design, and several passive elements (42, 43, 44, and 45) electrically connected to the magnetic element 41 respectively. Each passive element may be a resistor or capacitor. Furthermore, each passive element (42, 43, 44, and 45) may be selectively disposed on the upper surface or the lower surface of the substrate. In other words, since the substrate is used in the structure of the magnetic element according to the present invention, the magnetic element and the existing passive elements may be integrated into a means, and may also be integrated in the manufacturing process.

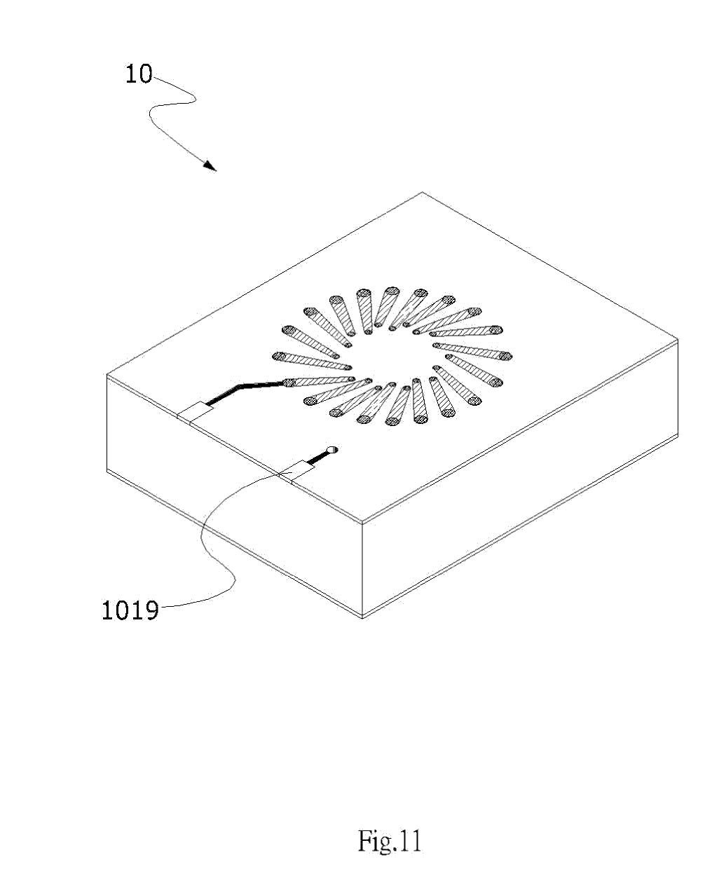

FIG. 11 shows a fourth embodiment of the present invention. Referring to FIG. 11, in the magnetic element 10 according to the present invention, more than one group of electrical pins 1019 are further formed on the upper surface or the lower surface, and the electrical pins 1019 are electrically connected to each circuit on the magnetic element 10. After being entirely manufactured, the magnetic element 10 may be electrically connected to an external circuit through the electrical pins 1019.

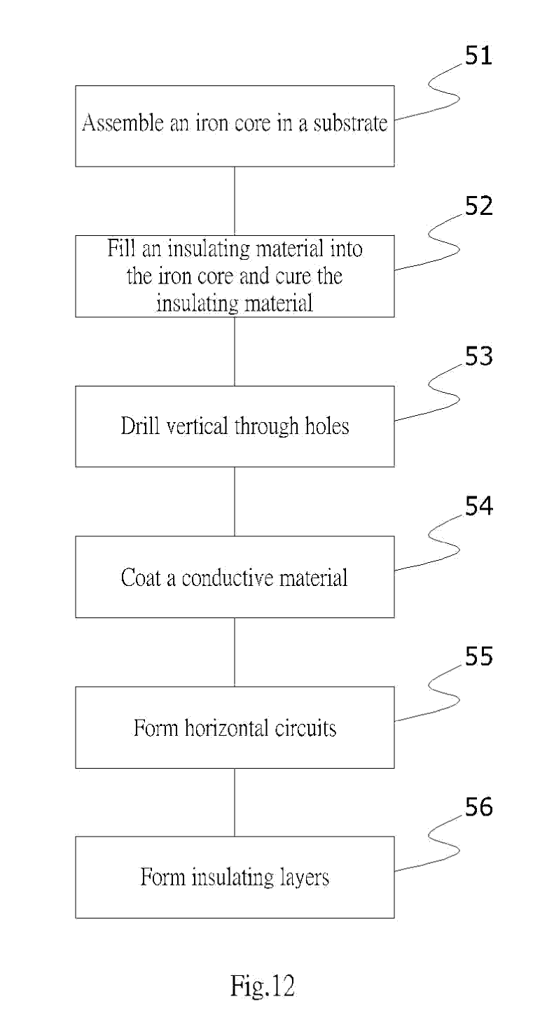

FIG. 12 is a schematic flow chart of a manufacturing method according to the present invention. Referring to FIG. 12, when the magnetic element according to the present invention is manufactured, the manufacturing method mainly includes the following steps, which may be obtained with reference to FIGS. 2 to 5 and FIG. 7 together.

In a first step, an iron core is assembled in a substrate (Step 51). Referring to FIG. 2, a hollow-shaped iron core 102 is assembled in an accommodation slot 1012 of a substrate 101.

In a second step, an insulating material is filled into the iron core, and the insulating material is cured (Step 52). Referring to FIG. 3, an insulating material is filled into a hollow space of the iron core 102, and the insulating material is cured to form an insulator 1021.

In a third step, vertical through holes are drilled (Step 53). Referring to FIG. 3, a semi-finished product after being assembled through the above steps is drilled. A drilled position for each hole position is located on an end edge of the accommodation slot 1012 and an inner edge area of the iron core 102, so as to form several vertical through holes (1013 and 1014) penetrating the substrate 101.

In a fourth step, a conductive material is filled (Step 54). Referring to FIG. 4, a conductive material 1015 is coated on an upper surface and a lower surface of the substrate 101, and each vertical through hole (1013 and 1014) is filled with the conductive material 1015. After being filled up with the conductive material, each vertical through hole (1013 and 1014) forms each vertical circuit (1016 and 1017) respectively.

In a fifth step, horizontal circuits are formed (Step 55). Referring to FIG. 5, several first horizontal circuits 1011 and several second horizontal circuits 1018 are respectively formed on the upper surface and the lower surface of the substrate through a photoelectric process, for example, exposure, development, and etching. Each first horizontal circuit 1011, each second horizontal circuit, and each vertical circuit (1016 and 1017) complete a continuous electrical connection respectively, so as to form a coil for surrounding the iron core 102.

In a sixth step, insulating layers are formed (Step 56). Referring to FIG. 7, an insulating layer is respectively formed on the upper surface and the lower surface of the substrate 101, and the manufacturing process of the magnetic element 10 is completed.

The description of the above manufacturing process is a preferred manufacturing process of the magnetic element 10 according to the present invention. During the manufacturing process, a jig may be used to provide a simultaneous limiting function for each component, such that when the components are assembled with one another, the accurate positioning effect can be achieved. Furthermore, after each component has been assembled, the vertical through holes are drilled and the horizontal circuits are formed in a unified manner, such that the first horizontal circuits and the second horizontal circuits can complete the electrical connection together with each vertical circuit more accurately, and the pitch and the amount of formed coils may be entirely standardized, thereby effectively improving a yield of finished products. However, the above described manufacturing process is only one preferred manufacturing process according to the present invention, and does not intend to limit a sequence of the steps.

As described above, in the present invention, through the substrate having the horizontal circuits and the vertical circuit disposed thereon, the iron core can complete the coil winding accurately, thereby improving the yield. Accordingly, after the present invention is implemented, the magnetic element capable of being easily assembled and having accurate electrical connection points and a high yield, and the method for manufacturing the same can be achieved.

The invention being thus described, it will be obvious that the same may be varied in many ways. Such variations are not to be regarded as a departure from the spirit and scope of the invention, and all such modifications as would be obvious to one skilled in the art are intended to be included within the scope of the following claims.

What is claimed is:

1. A magnetic element, assembled in an electronic device, the magnetic element comprising:
a substrate, having an accommodation slot formed thereon, having a first horizontal circuit and a second horizontal circuit respectively disposed on an upper surface and a lower surface thereof adjacent to an end edge of the accommodation slot, and having a first vertical circuit, wherein two ends of the first vertical circuit are electrically connected to one end of the first horizontal circuit and one end of the second horizontal circuit respectively;
an iron core, assembled in the accommodation slot, wherein a central area of the iron core is filled with an insulator, a second vertical circuit is disposed in the insulator and vertically penetrates the insulator, such that the other end of the first horizontal circuit and the other end of the second horizontal circuit of the substrate are connected to the second vertical circuit to complete an electrical conduction; and
an insulating layer, coated on the surfaces of the substrate.

2. The magnetic element according to claim 1, wherein the magnetic element forms a transformer.

3. The magnetic element according to claim 1, wherein the magnetic element forms an inductor.

4. The magnetic element according to claim 1, wherein the substrate has several passive elements disposed on the surfaces thereof.

5. The magnetic element according to claim 1, wherein the substrate has more than one group of electrical pins disposed on the surfaces thereof.

6. A method for manufacturing a magnetic element, comprising:
a first step, assembling a hollow iron core in an accommodation slot of a substrate;
a second step, filling an insulating material into a hollow space of the iron core, and curing the insulating material to form an insulator;
a third step, drilling a semi-finished product after being assembled through the above steps, wherein a drilled position for each hole position is located on an end edge of the accommodation slot and an inner edge area of the iron core, so as to form several vertical through holes penetrating the substrate;
a fourth step, coating a conductive material on an upper surface and a lower surface of the substrate, and filling up each of the vertical through holes with the conductive material, wherein after being respectively filled up with the conductive material, the vertical through holes form several vertical circuits;
a fifth step, forming several first horizontal circuits and several second horizontal circuits on the upper surface and the lower surface of the substrate respectively by using a photoelectric process, and completing a continuous electrical connection by using each of the first horizontal circuits, each of the second horizontal circuits, and each of the vertical circuits respectively, so as to form a coil surrounding the iron core; and
a sixth step, forming an insulating layer on the surfaces of the substrate.

7. The method for manufacturing a magnetic element according to claim 6, wherein the photoelectric process is exposure.

8. The method for manufacturing a magnetic element according to claim 6, wherein the photoelectric process is development.

9. The method for manufacturing a magnetic element according to claim 6, wherein the photoelectric process is etching.
